(19) United States
(12) Patent Application Publication
(10) Pub. No.: US 2012/0032687 A1
(43) Pub. Date: Feb. 9, 2012

(54) DETECTION APPARATUS FOR DETECTING ELECTRIC FIELD DISTRIBUTION OR CARRIER DISTRIBUTION BASED ON THE INTENSITY OF HIGH-ORDER HARMONICS

(76) Inventors: Mikio KYOMASU, Shizuoka (JP); Mitsumasa Iwamoto, Tokyo (JP); Takaaki Manaka, Tokyo (JP); Dai Taguchi, Tokyo (JP); Tetsushu Karasuda, Tokyo (JP); Masaki Sakakibara, Kanagawa (JP); Fumihiro Takahashi, Shizuoka (JP)

(21) Appl. No.: 13/020,149

(22) Filed: Feb. 3, 2011

(30) Foreign Application Priority Data
Aug. 4, 2010 (JP) 2010-175396

(51) Int. Cl. G01R 27/28

(52) U.S. Cl. 324/612

(57) ABSTRACT

A detection apparatus having means for evaluating generation and disappearance of a carrier is provided. A detection apparatus detects, on the basis of high-order harmonics, an electric field distribution or a carrier distribution between electrodes arranged on an object to be observed. The detection apparatus includes an emission unit for emitting a fundamental wave to the object, a detection unit for detecting the high-order harmonics generated according to the electric field distribution or the carrier distribution in the object when a voltage is applied to the object, an excitation emission unit for emitting an excitation light for generating a carrier in the object, and a control signal output unit for outputting a second signal to cause the excitation emission unit to emit the fundamental wave to the object on the basis of a first signal of the excitation emission unit, and outputting a third signal to cause the detection unit to detect the high-order harmonics, wherein the control signal output unit is configured to change a time interval from when the first signal is output to when the second and third signals are output.

### BACKGROUND OF THE INVENTION

1. Field of the Invention

The present invention relates to a detection apparatus for detecting an electric field distribution or a carrier distribution on the basis of the intensity of high-order harmonics.

2. Description of the Related Art

In the field of electronic engineering, it is very important to clarify dynamic characteristics of carriers in an object. Various methods (such as TOF method explained later) have hitherto been developed to evaluate dynamic characteristics of carriers. On the other hand, a method for inputting a fundamental wave and measuring mobility of carriers based on high-order harmonics thereof has been developed.

In recent years, organic electronic devices using organic materials such as organic illumination, organic solar cells, organic FETs (Field Effect Transistors), and the like particularly attracted attention. This is because the organic electronic devices have characteristics such as flexibility, which are different from those of ordinary electronic devices. Also in these organic electronic devices, it is very important to evaluate dynamic characteristics of carriers when devices and the like are developed. The dynamic characteristics of carriers mean various characteristics such as carrier injection, carrier accumulation, carrier transport, carrier generation, and disappearance.

TOF (Time of Flight) method, i.e., one of methods for evaluating dynamic characteristics of carriers (in particular, mobility of carriers), will be hereinafter explained.

FIG. 18 is an explanatory diagram for illustrating the TOF method. In the TOF method, as shown in FIG. 18, a power supply E1 is used to apply a voltage to a sample 203 held between a pair of electrodes 200, 201. Laser light is emitted to the sample 203 from the side of the electrode 200 when the voltage is applied to the sample. The emitted laser light generates electrons in proximity to the electrode 200 in the sample 203. The generated electrons proceed toward the electrode 201 according to an electric field. Then, an ampere meter 202 connected to the electrode 201 measures the amount of electric current between the electrode 201 and the ground. The electrode 200 is transparent to the laser light. Based on the configuration, mobility of carriers is obtained as follows. First, a traveling time of carriers between the electrodes is obtained based on the measured waveform of the electric current, and the mobility of carriers is obtained based on the obtained traveling time of carriers and the distance between the electrodes set in advance. Japanese Patent Application Laid-Open No. 2006-135125 describes an apparatus used for the TOF method.

A method for measuring a carrier distribution includes an SHG (Second-Harmonic Generation) method. As shown in FIG. 17, this employs the detection method based on the intensity of the second harmonic of light. In this method, an emission unit and a detection unit are provided. The emission unit emits a fundamental wave onto an object to be observed. The detection unit detects the second harmonic generated according to an electric field distribution or a carrier distribution during application of a voltage. A control unit for driving the emission unit and the detection unit controls a time interval of oscillation and a detection signal, so as to detect the mobility of carriers.

Operation of this method will be explained with reference to FIG. 17. FIG. 17 is a schematic configuration diagram illustrating a detection apparatus (hereinafter simply referred to as an SHG intensity distribution obtaining apparatus) 100 for the second harmonic (high-order harmonics) used for observing an electric field distribution or a carrier distribution.

The conventional detection apparatus detects, on the basis of the intensity of the second harmonic, an electric field distribution or a carrier distribution between electrodes provided in an object to be observed. The conventional detection apparatus includes an emission unit for emitting a reference wave onto the object, a detection unit for detecting the second harmonic generated according to the electric field distribution or the carrier distribution during application of a voltage, a signal for controlling the fundamental wave, and a signal for controlling the voltage. The intervals therebetween are configured to be changeable, so that the conventional detection apparatus detects the mobility.

As shown in FIG. 17, the SHG intensity distribution obtaining apparatus 100 includes a laser oscillator (light source) 1, a wavelength converter 2, a mirror RM, an attenuation filter 3, a polarizer 4, a low pass filter 5, a half mirror HM1, and an objective lens OL. In addition, the SHG intensity distribution obtaining apparatus 100 includes a stage 11 on which a pentacene FET (object to be observed) 50 is placed. In addition, the SHG intensity distribution obtaining apparatus 100 includes a half mirror HM2, a band-pass filter 12, a polarizer 13, a band-pass filter 14, and a photomultiplier tube (PMT) 15. In addition, the SHG intensity distribution obtaining apparatus 100 includes a lens 17 and an image capturing device 18. In addition, the SHG intensity distribution obtaining apparatus 100 includes a control signal output unit 30 and a processing unit 16.

In the SHG intensity distribution obtaining apparatus 100, laser light (fundamental wave) excited by the laser oscillator 1 and output from the wavelength converter 2 is emitted onto the pentacene FET 50. The photomultiplier tube 15 detects the second harmonic generated by the pentacene FET 50. The control signal output unit 30 controls a time when a pulse signal S2 is output to a source electrode 6 of the pentacene FET 50, and controls a time when a pulse signal S3 is output to a switch device 21. Therefore, it is possible to change the time when the voltage is actually applied to the pentacene FET 50 (the first point in time=voltage application time) and the time when the laser is emitted onto the pentacene FET 50 (the second point in time=laser emission time). After the pulse signal S3 is output to the switch device 21, the laser oscillator 1 outputs laser light.

For each of a plurality of portions of channels that may be formed in the pentacene FET 50 (carrier transport passage), the intensity distribution of the second harmonic is measured using the SHG intensity distribution obtaining apparatus 100 under a plurality of conditions in each of which a time interval between the voltage application time and the laser emission time is different. As a result, transition of the electric field distribution or the carrier distribution in the channels of the pentacene FET 50 can be observed.

The laser oscillator 1 includes a flash lamp (excitation light source) 19, a rod 20, a switch device (switch unit) 21, reflection mirrors M1, M2, and a THG (Third Harmonic Generation) crystal 22. The laser oscillator 1 is a so-called solid laser device operating in Q-switching mode. The laser oscillator 1 outputs laser light (fundamental light or fundamental wave) having a predetermined pulse width. The laser oscillator 1 outputs laser light having a wavelength of 355 nm. The laser oscillator 1 serves not only as a light source but also as an emission unit.

The flash lamp 19 is a pumping excitation light source. The rod 20 is a material doped with Nd:YAG (laser medium). The reflection mirror M1 is provided at one side of the rod 20. The reflection mirror M2 is provided at the other side of the rod 20. An oscillator is constituted by the rod 20 and the reflection mirrors M1, M2. The switch device 21 is provided between the rod 20 and the reflection mirror M1.

When a high-level pulse signal (control signal) S1 is received from the control signal output unit 30, the flash lamp 19 outputs excitation light. The Nd:YAG doped in the rod 20 is excited by the excitation light pumped by the flash lamp 19. The Nd:YAG emits light when it changes from an excited state to a ground state. The light emitted from the rod 20 is amplified between the reflection mirror M1 and the reflection mirror M2, and the Nd:YAG in the excited state performs stimulated emission.

The switch device 21 is an electro-optical crystal. When a voltage is applied to the switch device 21, the switch device 21 becomes highly transparent to laser light (1064 nm). In other words, the switch device 21 is transparent to laser light when a voltage is applied thereto, but the switch device 21 is opaque to laser light when no voltage is applied thereto. In this case, while the pulse signal (control signal) S3 given by the control signal output unit 30 is at a high level, the switch device 21 becomes highly transparent to laser light. By controlling the switch device 21, the laser oscillator 1 outputs laser light (fundamental light or fundamental wave) having a predetermined pulse width.

The wavelength converter 2 uses an optical crystal to convert the wavelength of the laser light emitted from the laser oscillator 1. More specifically, the wavelength is converted from 355 nm into 1120 nm.

The reflection mirror RM disposed between the wavelength converter 2 and the attenuation filter 3 reflects the laser light output from the wavelength converter 2 so that the laser light proceeds toward the attenuation filter 3.

The attenuation filter 3 is a member for adjusting the intensity of the laser light. The pentacene FET 50, i.e., an object to be observed, is an organic device. Accordingly, the attenuation filter 3 attenuates the intensity of the laser light so as to prevent the pentacene layer 8 from being physically destroyed by the laser light emitted thereupon.

The polarizer 4 passes only laser light having an oscillation in a predetermined direction. In other words, the polarizer 4 improves the quality of polarization component of the laser light emitted onto the pentacene FET 50. The low pass filter 5 passes only light having a predetermined wavelength or more (having a predetermined frequency or less). In other words, in this case, light having a wavelength of 1120 nm passes through the low pass filter 5, but the low pass filter 5 blocks light having a wavelength of 710 nm or less. The half mirror HM1 provided between the low pass filter 5 and the objective lens OL reflects 50% of the laser light having passed through the low pass filter 5, so that the reflected laser light proceeds toward the objective lens OL. The objective lens OL condenses the laser light transmitted from the laser oscillator 1 to a predetermined position of the pentacene FET 50. At the same time, the objective lens OL passes 50% of the second harmonic emitted from the pentacene FET 50.

The half mirror HM2 outputs 50% of the light having passed through the half mirror HM1 to the band-pass filter 12. The half mirror HM2 outputs the remaining 50% of the light having passed through the half mirror HM1 to the image capturing device 18.

The band-pass filter 12 blocks light having a wavelength of 800 nm or more. The band-pass filter 12 blocks the laser light reflected by the pentacene FET 50, so that the reflected laser light (wavelength: 1120 nm) is not input into the photomultiplier tube 15.

The polarizer 13 passes only the second harmonic having an oscillation in a predetermined direction. In other words, the polarizer 13 improves the quality of polarization of the second harmonic input into the photomultiplier tube 15. The band-pass filter 14 is a filter for passing only the light in a band around the second harmonic (wavelength: 560 nm).

The photomultiplier tube 15 performs photoelectric conversion on the second harmonic incident to the photomultiplier tube 15. Electric field distribution is detected based on this electric signal.

### SUMMARY OF THE INVENTION

### Problems to be Solved by the Invention

An object of the conventional invention is to find injection, accumulation, and transportation, i.e., some of dynamic characteristics of an organic device. Therefore, no attention has ever been given to generation and disappearance. For this reason, although an apparatus that can be applied to a horizontal structure device such as a pentacene FET has been suggested, no means for analyzing a vertical structure has ever been reported, and no means for improving the resolution thereof has ever been considered.

Since the conventional apparatus is not aimed at generation and disappearance of a carrier, the carrier is injected upon voltage application. Thereafter accumulation is obtained as an electric field distribution, and transportation is obtained as a time function. Therefore, the conventional apparatus has no excitation mechanism and no mechanism for obtaining change of a carrier over time in synchronization with excitation.

When the generation and the disappearance of carrier are taken into consideration as a problem to be solved, process of disappearance in materials having different molecular structures are naturally considered to rely on the materials, but there is no detection means for solving the problem. Moreover, in order to solve this problem, there is no output uniformizing means for solving the problem, i.e., the output of high-order harmonics of Nd:YAG laser output relies on wavelength.

An organic device is expected to be applied to, e.g., electroluminescence considered to be used for displays and illuminations, photoelectromotive force considered to be used for solar cells, and an FET serving as an organic semiconductor. In any of the devices, it is important to know a vertical structure. Originally, the first and second devices are vertical devices, and although the third device, i.e., the FET, has a horizontal structure in a channel, but has a vertical structure in an MIS structure controlling the channel. Therefore, it is important to find the vertical structure from the high-order harmonics in order to find injection, accumulation, transportation, generation, and disappearance, which are dynamic characteristics of an organic device.

### Means for Solving the Problems

The present invention is made in view of the above viewpoints, and the present invention includes an emission unit for emitting a fundamental wave to an object to be observed, a detection unit for detecting the high-order harmonics generated according to an electric field distribution or a carrier distribution in the object when a voltage is applied to the object, and an excitation emission unit for emitting an excitation light for generating a carrier in the object, wherein a Z-axis polarizer passing an optical axis polarization component is provided between an objective lens and an emission unit for emitting the fundamental wave, wherein the present invention includes a control signal output unit 30 for outputting a second signal to cause the excitation emission unit to emit the fundamental wave to the object on the basis of a first signal of the excitation emission unit, and outputting a third signal to cause the detection unit to detect the high-order harmonics, and wherein the control signal output unit 30 is configured to change a time interval from when the first signal is output to when the second and third signals are output. Thus, the present invention provides means for evaluating generation and disappearance of the carrier.

The reason why the Z-axis polarizer is employed is as follows. The generation of the high-order harmonics at a position Z is given by the following expression.

P(2ω)=ε₀χ⁽³⁾E(0)E(ω)E(ω) (1)

In this case, E(ω) is an electric field of Z component of light, and E(0) is an electric field where the carrier is generated.

The output of the high-order harmonics from the entire organic film is given by the following expression.

I(2ω)∝|∫₀^{d}P_{Z}(2ω)dz|² (2)

In other words, a detection apparatus for emitting fundamental light having an electric field in an optical axis direction and measuring the output of the generated high-order harmonics is required.

This is the point that is different from a conventional invention, i.e., a detection apparatus described in Japanese Patent Application Laid-Open No. 2008-218957. For this reason, it is essential to employ a polarizer for polarization in the optical axis direction (Z-axis polarizer).

There are three methods for forming the Z-axis polarizer. The configuration thereof is shown in FIG. 2. In order to make the Z-axis polarizer, a material basically having a polarization function is formed in a circular shape, and only the polarization of the Z-axis component is generated by setting off the polarizations of the X, Y axes components. Since there are several ways to do this, the configurations thereof are shown below.

In FIG. 2A, the polarizer is formed using a photonic crystal, and polarization anisotropy is achieved by a deposition process in a longitudinal direction. When patterning process is set in a circular shape, the Z-axis polarization can be made. Thus, the Z-axis polarization can be easily achieved. However, there is a drawback in that an extinction ratio is highly dependent on a wavelength as shown in FIG. 3. Therefore, even if the characteristic of the extinction ratio is set at −20 dB, it is necessary to have a mechanism for replacing at least four filters in order to cover a wavelength area from 800 to 1200 nm to be analyzed.

The method as shown in FIG. 2B is a method using liquid crystals. The polarization characteristics of the liquid crystal depend on the molecular structure. In other words, the polarization characteristics are achieved by aligning the arrangement direction of the liquid crystals. Accordingly, the characteristic of the extinction ratio itself is inferior to that of the photonic crystal, but the dependency on the wavelength is low. Therefore, the liquid crystals are characterized in supporting all the wavelengths with one filter, and are suitable for the present invention.

FIG. 2C is a Z-axis polarizer using a conical Brewster prism, in which functions are achieved by setting a conical angle at 68.4 degrees and forming a multi-layer film. In this case, however, it is difficult to position a conical prism. Like the photonic crystal, the wavelength dependency of the extinction ratio is high, which is not suitable for practical application.

Another method, i.e., a method for attaching Polarcors (TM) in a circular shape like a wooden mosaic work, may be considered. In this method, the wavelength decency of the extinction ratio is considered to be low, and therefore, this method is an effective method. In any case, the Z-axis polarizer is structured using any method, and an object of the present invention can be achieved.

Injection, accumulation, and transportation of charges can be observed and measured by measuring them using an organic FET by using parameters, i.e., a time interval between voltage application and fundamental light and an emission position in a lateral direction thereof. However, when generation and disappearance are measured, it is necessary to give an electric field perpendicular to a joint surface with fundamental wave, give excitation light for generating a carrier, and measure a time until excitation light disappears.

In other words, it is necessary to have an emission unit for giving a fundamental wave (fundamental light), provide a Z-axis polarizer between the emission unit and an objective lens to arrange a polarization plane in the Z-axis, and provide a mechanism between the objective lens and a detection unit for detecting the high-order harmonics so as to introduce excitation light. In addition, in order to easily measure the time, the excitation light requires a light source operating at a high speed, and unless setting is made outside of a detection wavelength area, a photomultiplier tube may be saturated, and the high-order harmonics may not be detected. Therefore, it is desired to set a wavelength in an absorbable range of an organic solar cell, an organic EL, and an organic semiconductor except for a detection wavelength range. For example, blue laser of 405 nm and red laser of 685 nm are suitable for this. When the above excitation light is used, the detection wavelength range from 420 to 600 nm is ensured, and a fundamental wave from 840 to 1200 nm can be supported.

Many of organic devices have properties similar to insulating materials, and most of them are designed to have a thicknesses of 1 μm or less so as to improve the conductivity. Therefore, the location accuracy in the Z axis direction is required to be about ±5 nm. A currently-available actuator achieving this is a piezo-actuator. The piezo-actuator has a movable range of as much as 100 μm, and when a heavy objective lens is driven, it is about 20 μm. Since this level of movable range affects operability, two-stage structure is employed to mount the piezo-actuator on the Z-stage, so that the operability and the resolution are ensured.

In this configuration, the Z-stage takes care of rough adjustment, and the piezo-actuator takes care of fine adjustment, so that this achieves a movable range of ±20 mm and a resolution of ±5 nm.

In order to obtain information about an interface at the joint portion, it is important to obtain information about generation and disappearance of carriers in a P-type material and an N-type material, and it is effective to make use of the fact that the high-order harmonics have characteristics intrinsic to materials.

To do so, it is effective for the detection apparatus to have a function for detecting this intrinsic wavelength. This function sweeps the wavelength of the fundamental wave generated by the emission unit, measures the intensity of high-order harmonics generated, and determine the wavelength at the peak value. However, this operation has three problems. The first problem is that a refractive index of glass used for the lens has wavelength dependency. Accordingly, it is necessary to correct the focal points of two groups of lenses, i.e., a waveform modifying unit and an objective lens. Another problem is that the output of the laser generating the fundamental wave has wavelength dependency, and is based on wavelength dependency of an AR coat of the used objective lens.

The following measures are taken to solve the former. As shown in FIG. 4, a waveform modifying unit 52 includes an iris diaphragm 25, an attenuation filter 3, a rotation control plate 26, a convex lens 37, a concave lens 38, and an X-stage 31. The iris diaphragm 25 modifies the beam of the fundamental wave, and the convex lens 37 and the concave lens 38 are used to control the diameter of the beam incident upon the objective lens OL. Therefore, when the fundamental wave is changed, the focal points of the convex lens 37 and the concave lens 38 change. This correction is performed as follows.

An image capturing device 18 is provided in order to adjust the optical axis of the Z-axis polarizer. As shown in FIG. 4, this configuration includes a slide-type reflection mirror RM′, an attenuation filter 3, a polarizer 4, and an image capturing device 18. The beam outputted from the waveform modifying unit 52 may be adjusted so that collimated light is emitted as much as possible. Therefore, when a control unit 24 drives an actuator 23 attached to a wavelength converter 2 to change a fundamental wave, the position of the concave lens 38 mounted on the X-stage 31 is moved, and the beam waveform is observed. The wavelength and the position of the X-stage 31 are stored when the beam waveform is the sharpest, and the position of the actuator 23 and the position of the X-stage 31 are moved in a synchronized manner. Thus, this problem is solved.

The focal point of the objective lens is corrected as follows. Since the lens to be used has a field of vision of 0.22 mm, a detector having a smaller light-receiving diameter than this is provided at a sample position. The wavelength and the position of the piezo-actuator 29 for making the maximum output of the detector are obtained. The result thereof is stored, and the actuator 23 is moved in a synchronized manner. Thus, the problem is solved.

The correction of the high-order harmonics involves two factors. The first factor is uniformization of the intensity of the incident fundamental wave, and the other factor is correction of the output of the high-order harmonics. These are considered from the generation mechanism, and since they cannot be performed at a time, they are considered while they are divided into two.

The first factor is uniformization of incident side. As shown in FIG. 5, the output of the wavelength converter 2 changes about twice in a wavelength range from 800 to 1200 nm. Furthermore, the wavelength characteristic of the attenuation filter and the wavelength characteristic of the AR coat of the objective lens are added. This correction is performed as follows. The detector is placed at the sample position, and the rotation control plate 26 is driven based on the measurement value thus obtained. The uniformization is achieved by selecting the attenuation filter 3 so as to uniformize the intensity in a wavelength range from 800 to 1200 nm as much as possible.

The characteristics of the light receiving side result from the characteristic of the AR coat of the objective lens OL and the characteristic of the band-pass filters 14, 14′. The characteristics are corrected by measuring the wavelength dependency and storing relationship between the result and the wavelength.

The dimension of the vertical structure of the organic device is very thin, i.e., 1 μm or less, as described above. Accordingly, it is impossible to identify the interface surface thereof by using a measuring instrument. In the system according to the present invention, only the piezo-actuator ensures the accuracy. Therefore, it is the only possible method to identify the interface surface by using the output of the high-order harmonics of the piezo-actuator and the wavelength characteristic intrinsic to a material.

The intrinsic wavelength can be identified by the above method. Therefore, when the piezo-actuator 29 is driven while the Z-stage 39 is fixed, the high-order harmonics of respective materials are generated according to the positions of the materials as shown in FIG. 6. Accordingly, the data are normalized with the peak value of each of them being 1. When relationship between the position and the intensity is obtained, an intersecting point of the normalized intensities is a position corresponding to the interface.

There are three factors for improving the resolution in the optical axis (Z axis) direction. The first factor is that the SHG is output in proportional to a square of the intensity of the electric field. Therefore, since the SHG output is generated according to square-law characteristic with respect to the intensity of the light formed by the lens, the resolution improves in the optical axis direction.

Another factor results from the use of the Z-axis polarizer. FIG. 8 is illustrates relationship between an numerical aperture (NA) and a Z-axis component of polarization. FIG. 8 indicates that a smaller NA makes a smaller Z-axis component of polarization. This is because, when the beam is not condensed, X, Y axes components are not sufficiently set off. When this idea is applied to the spatial distribution of the intensity of the fundamental wave in the space, it is understood that the polarized component increases at the point where the light is condensed but the polarized component decreases at a point away from the point where the light is condensed, which suppresses the conversion into the SHG light. The above relationship is shown in FIG. 7.

The resolution in the Z-axis direction can be improved by increasing the apparent NA. This can be achieved by covering the center of the beam with slits and the like. In other words, instead of the iris diaphragm 25 of the waveform modifying unit, donut-shaped slits are provided as shown in FIG. 9.

In order to improve the resolution in the Z-axis direction, it is necessary to design the objective lens used for emitting light onto the object to be observed such that the objective lens has a low aberration with respect to the fundamental wave. In order to improve the sensitivity of detection of the SHG light, the design area of the AR coat needs to be in a range from 400 to 600 nm. Since it is impossible, in terms of optics, for the AR coat to cover the range from 400 to 1200 nm, priority is given to the area from 400 to 600 nm. In this case, although the transmittance characteristic in the range from 800 to 1200 nm is sacrificed, the output of the laser of the fundamental wave emission unit is high, i.e., it is at such a high level that the output is attenuated by the attenuation filter. Therefore, the reduction of the transmittance caused by the AR coat can be sufficiently covered.

This apparatus measures the lifetime as follows. The excitation light for generating the carrier is emitted onto the object to be observed, so that the carrier is generated. Then, the organic material is distorted by the electric field generated by the carrier, and a non-linear component is generated. Even after the excitation light is cut off, the non-linear component is held as long as the carrier does not disappear. Therefore, the fundamental wave is emitted onto the object to be observed, and SHG light generated therefrom is detected, whereby the measurement is performed. Therefore, when this operation is performed with respect to a temporal axis, the disappearance process of the carrier can be measured, based on which the lifetime can be measured.

For example, when the object to be observed is a solar cell, it is constituted by, for example, a P-type material, i.e., pentacene, and an N-type material, C60. Since they make hetero junction, the hole disappearance process and the electron disappearance process are different from each other. The detection means using the SHG light selects a fundamental wave to find an electric field intrinsic to a material. Therefore, the disappearance process for each carrier can be found. In other words, the lifetimes of each of the electron and the hole can be measured by measuring the lifetime intrinsic to each wavelength.

According to the present invention, injection, accumulation, transportation, generation, and disappearance, i.e., dynamic characteristics of an organic device, can be found in terms of lifetime, and difference of disappearance processes using difference of materials can be found. This provides means for considering the method for reviewing improvement means of an interface from various perspectives of materials, structures, and processes.

### BRIEF DESCRIPTION OF THE DRAWINGS

FIG. 1 is a figure illustrating an example of configuration of a detection apparatus according to the present invention;

FIGS. 2A to 2C is a figure illustrating three methods for forming a Z-axis polarizer according to the present invention, wherein FIG. 2A is a method using a photonic crystal, FIG. 2B is a method using a liquid crystal, and FIG. 2C is a method using a conical Brewster prism;

FIG. 3 is a figure illustrating an extinction ratio characteristics of a Z-axis polarizer using a photonic crystal;

FIG. 4 is a figure illustrating an example of configuration of a waveform modifying unit according to the present invention;

FIG. 5 is a figure illustrating output characteristics of the wavelength converter according to the present invention;

FIG. 6 is a figure illustrating a method for identifying a position of an interface according to the present invention;

FIG. 7 is an explanatory drawing of a Z-axis resolution according to the present invention;

FIG. 8 is a figure illustrating relationship between an NA and a Z-axis component of polarization according to the present invention;

FIG. 9 is a figure illustrating a slit pattern according to the present invention;

FIG. 10 is a figure illustrating an example of configuration of a waveform modifying unit according to the present invention;

FIGS. 11A to 11C are figures illustrating a Z-axis polarization unit according to the present invention, wherein FIG. 11A is a figure illustrating a configuration of the Z-axis polarization unit, FIG. 11B is a figure illustrating a cross section of a beam when there is no polarizer, and FIG. 11C is a figure illustrating a cross section of beam after the beam has passed through the polarizer;

FIG. 12 is a figure illustrating an example of configuration of a detection unit according to the present invention;

FIG. 13 is a figure illustrating an example of specification of a filter according to the present invention;

FIG. 14 is a figure illustrating timing of operation of a processing unit according to the present invention;

FIG. 15 is a figure illustrating wavelength sweeping according to the present invention;

FIG. 16 is a figure illustrating square-law characteristic of SHG light at an intrinsic wavelength;

FIG. 17 is a figure illustrating a configuration of a conventional detection apparatus; and

FIG. 18 is a figure illustrating a conventional TOF method.

### PREFERRED EMBODIMENT OF THE INVENTION

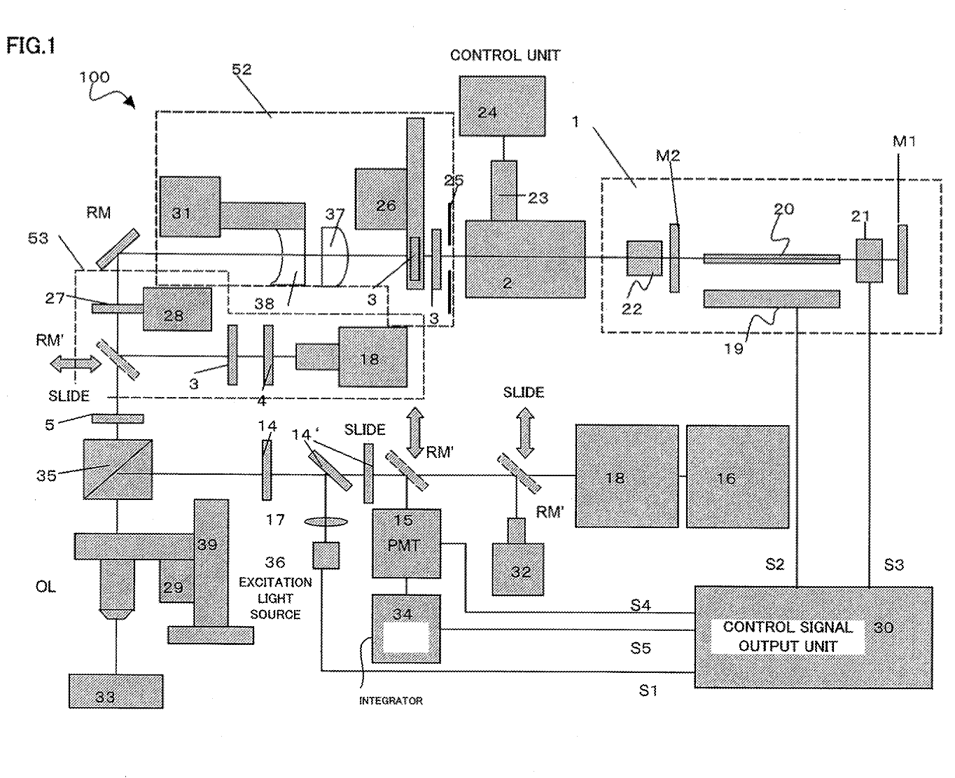

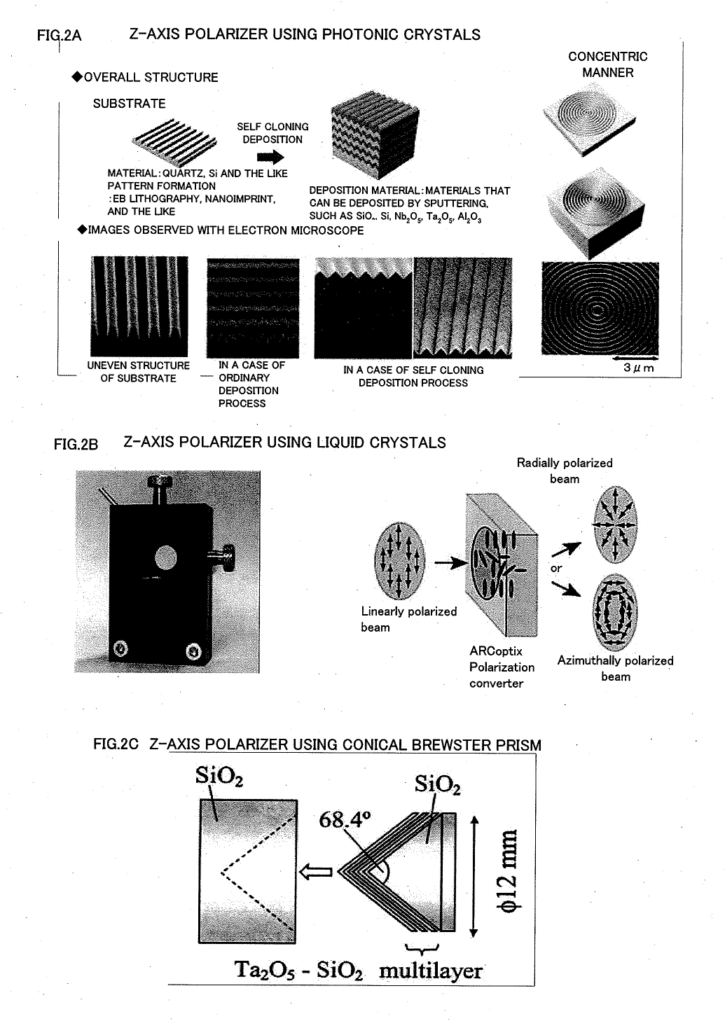

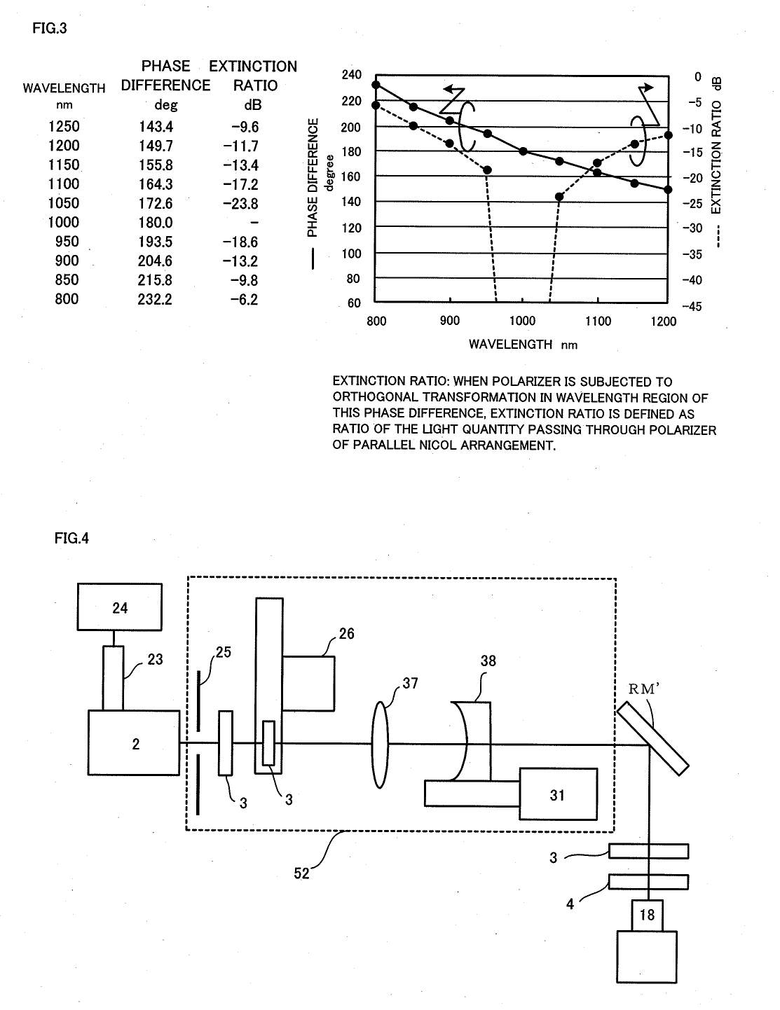

As shown in FIG. 1, an SHG intensity distribution obtaining apparatus 100 includes a laser oscillator (light source) 1, a wavelength converter 2, a waveform modifying unit 52, a reflection mirror RM, an attenuation filter 3, a polarizer 4, a Z-axis polarization unit 53, a low pass filter 5, a slide-type reflection mirror RM′, an objective lens OL, and an excitation light source (excitation emission unit) 36. In addition, the SHG intensity distribution obtaining apparatus 100 includes a stage (not shown) on which an organic solar cell (object to be observed) is placed. In addition, the SHG intensity distribution obtaining apparatus 100 includes a slide-type reflection mirror RM′, band-pass filters 14, 14′, and a photomultiplier tube 15. In addition, the SHG intensity distribution obtaining apparatus 100 includes a lens 17 and an image capturing device 18. In addition, the SHG intensity distribution obtaining apparatus 100 includes a control signal output unit 30.

In the SHG intensity distribution obtaining apparatus 100, in an electric field induced based on carriers accumulated in an organic solar cell by excitation light, laser light (fundamental wave) which is excited by the laser oscillator 1 and whose wavelength is converted by the wavelength converter 2 is emitted onto the organic solar cell, and the second harmonic generated by the organic solar cell is detected by the photomultiplier tube 15. The processing unit 16 performs ON/OFF control of the excitation light source 36 with a pulse signal S1, and thereafter, controls a time when a pulse signal S3 is output to the switch device 21, controls a time when the gate of the photomultiplier tube 15 is controlled with a pulse signal S4, and controls an integrator 34 with a pulse signal S5, thus controlling a time when data are sampled. With this, a change of carriers induced by the excitation light source 36 over time within the organic solar cell after shut off of the excitation light source 36 can be found by varying a time interval of a pair of pulse signals S3, S4, S5 and the pulse signal S1. When the SHG intensity distribution obtaining apparatus 100 is used to accurately change the position in an optical axis direction of the organic solar cell, relationship between an SHG output intensity and a decay time thereof corresponding to the electric field based on the accumulation of carriers in the organic solar cell can be derived.

The laser oscillator 1 includes a flash lamp (excitation light source) 19, a rod 20, a switch device (switch unit) 21, reflection mirrors M1, M2, THG (Third Harmonic Generation) crystal 22. The laser oscillator 1 is a so-called solid laser device operating in Q-switch mode. The laser oscillator 1 outputs laser light having a predetermined pulse width (fundamental light or fundamental wave). The laser oscillator 1 outputs laser light having a wavelength of 355 nm. The laser oscillator 1 serves not only as a light source but also as an emission unit.

The flash lamp 19 is an excitation light source for pumping. The rod 20 is a material doped with Nd:YAG (laser medium). The reflection mirror M1 is provided at one side of the rod 20. The reflection mirror M2 is provided at the other side of the rod 20. An oscillator is constituted by the rod 20 and the reflection mirrors M1, M2. The switch device 21 is provided between the rod 20 and the reflection mirror M1.

When a high-level pulse signal (control signal) S2 is received from the control signal output unit 30, the flash lamp 19 outputs an excitation light. The Nd:YAG doped in the rod 20 is made into excitation light by the excitation light pumped by the flash lamp 19. The Nd:YAG emits light when it changes from an excited state to a ground state. The light emitted from the rod 20 is amplified between the reflection mirror M1 and the reflection mirror M2, and the Nd:YAG in the excited state performs stimulated emission.

The switch device 21 is an electro-optical crystal. After a voltage is applied to the switch device 21, the switch device 21 becomes highly transparent to laser light (1064 nm). In other words, the switch device 21 is transparent to laser light when a voltage is applied thereto, but the switch device 21 is opaque to laser light when no voltage is applied thereto. In this case, while the pulse signal (control signal) S3 given by the control signal output unit 30 is at a high level, the switch device 21 becomes highly transparent to laser light. By controlling the switch device 21, the laser oscillator 1 outputs laser light having a predetermined pulse width (fundamental light or fundamental wave).

The wavelength converter 2 uses an optical crystal to convert the wavelength of the laser light emitted from the laser oscillator 1. More specifically, the wavelength is converted from 355 nm into 800-1120 nm.

The attenuation filter 3 is a member for adjusting the intensity of the laser light. An organic solar cell, i.e., an object to be observed, is an organic material. Accordingly, the attenuation filter 3 attenuates the intensity of the laser light so as to prevent the organic solar cell from being physically destroyed by the laser light emitted thereupon.

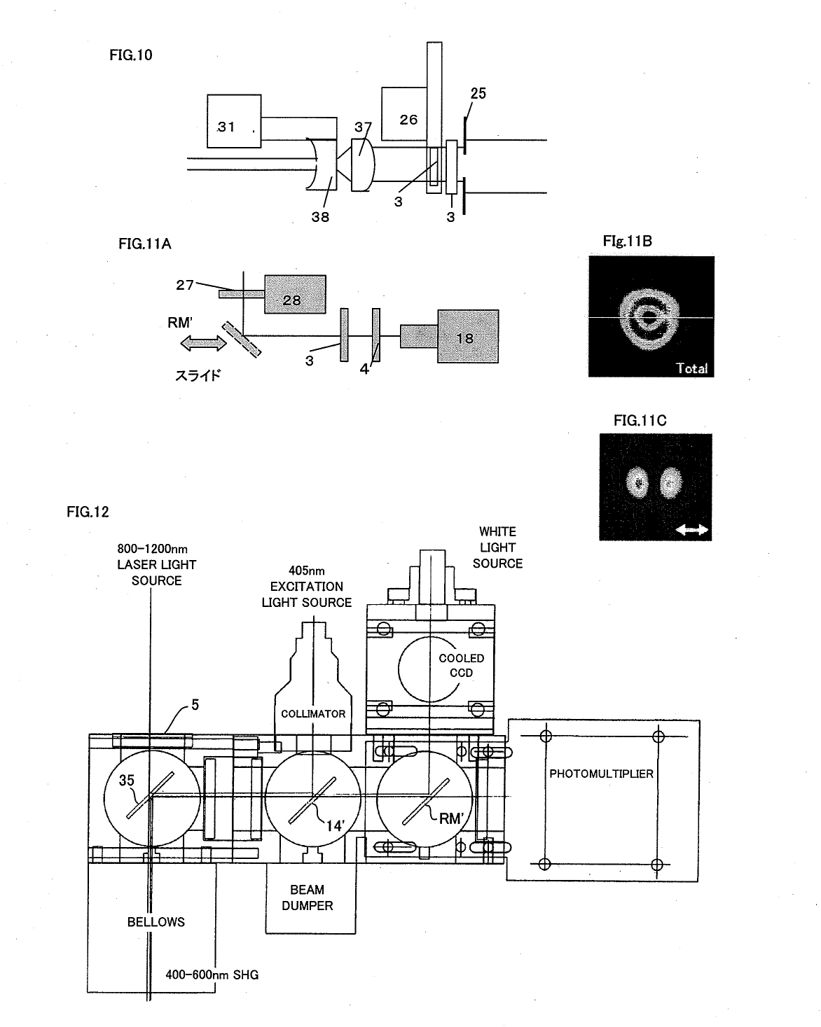

FIG. 10 illustrates a configuration of the waveform modifying unit 52. The light output from a wavelength conversion unit 2 has a collimated beam shape having a diameter of about 5 mm. Accordingly, the light is controlled by an iris diaphragm 25 to have a diameter of 5 mm, and the light passes through the attenuation filter 3 and the attenuation filter 3 attached to a rotation control plate 26. Then, the beam diameter of the light is controlled by a convex lens 37, and the light is made into a collimated beam by the concave lens 38. Thus, the light is transmitted according to an aperture of an objective lens OL.

The sweeping range of the fundamental wave is 800 nm to 1200 nm. Accordingly, the focal points of lenses 37, 38 change. In order to correct this, the concave lens 38 is mounted on an X-stage 31, and the position thereof is driven in synchronization with the wavelength of the fundamental wave, so that the focal points are corrected.

FIGS. 11A to 11C illustrates a Z-axis polarization unit 53 including a Z-axis polarizer 27 and an adjustment system thereof. Due to the principle of a Z-axis polarization, the Z-axis polarization is to set off and extract X, Y polarizations, and therefore, it is necessary to make the beam position and the position of the Z-axis polarizer be the same. This operation is performed with the configuration as shown in FIG. 11A. The light having passed through the Z-axis polarizer 27 is reflected by a slide-type reflection mirror RM′, and the light passes through the attenuation filter 3 and the polarizer 4. Then, the light is guided to the image capturing device 18. The light that has not passed through the polarizer 4 has a circular beam shape as shown in FIG. 11B. However, the light having passed through the polarizer 4 has a butterfly shape as shown in FIG. 11C. The XY stage 28 is moved and adjusted so as to make this shape symmetrical.

The adjustment system as shown in FIGS. 11A to 11C is also used to correct the focal point in the modifying of the waveform as described above. In this case, FIG. 11B is obtained. Accordingly, the X-stage 31 is driven so as to adjust the position at which this beam becomes in the sharpest focus, and this position is memorized. The focal point is corrected by synchronizing the wavelength of the fundamental wave and the memorized position of the X-stage 31. After the above correction is made, the slide-type reflection mirror RM′ is moved, so as to pass the beam.

FIG. 12 illustrates an example of configuration of the detection unit. The fundamental wave having a wavelength of 800 to 1200 nm passes through the low pass filter 5 and a Dichroic mirror 35, passes through a bellows, and enters into the objective lens OL. The bellows ensures a movable range of the objective lens OL, and fixes the detection unit.

The SHG light is reflected by the Dichroic mirror 35. The SHG light passes through two kinds of band-pass filters 14, 14′, and the SHG light is guided to the photomultiplier tube 15. The excitation light having a wavelength of 405 nm passes through a collimator lens 17, and is reflected by the band-pass filter 14′. The excitation light is reflected by the Dichroic mirror 35, and is incident upon the objective lens OL.

The light reflected by the slide-type reflection mirror RM′ is observed with the image capturing device 18. White light is incident from a slide half mirror (not shown).

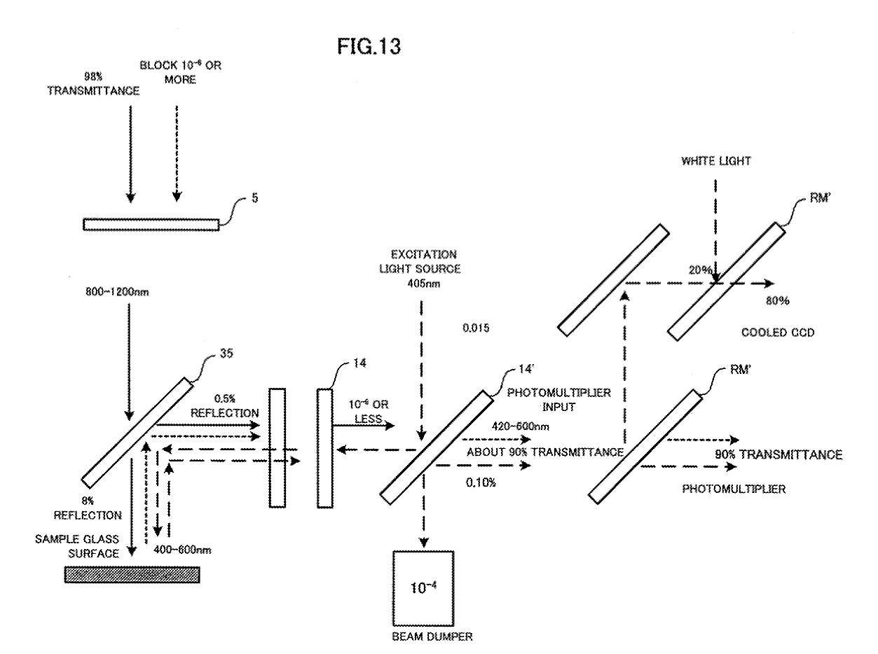

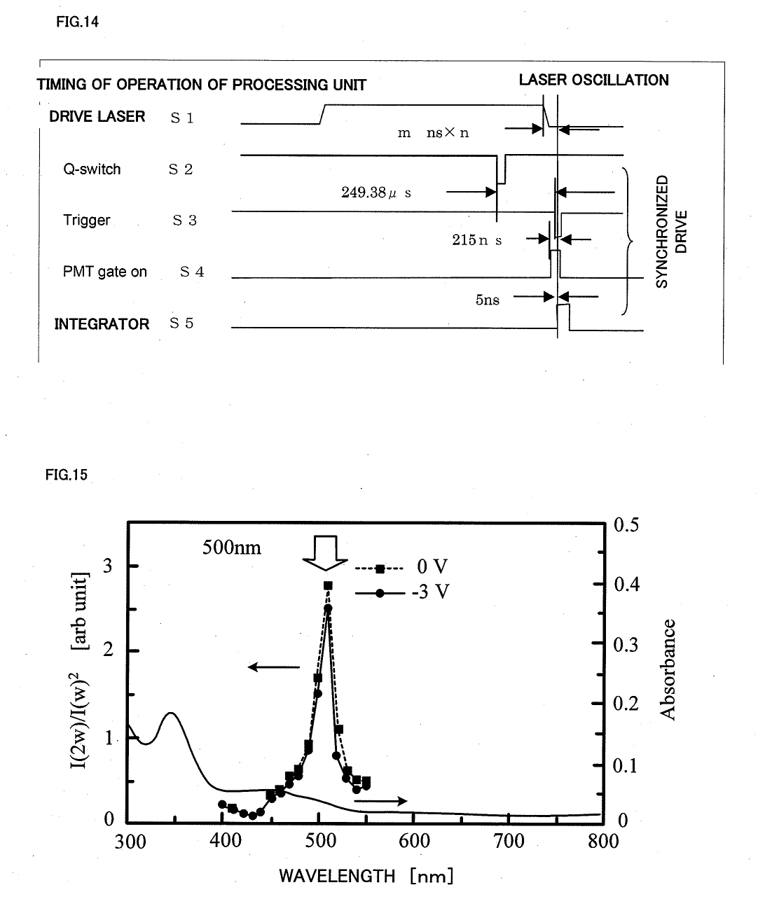

FIG. 13 illustrates an example of specification of a filter. The low pass filter 5 has a transmittance of 1×10⁻⁶ or less in a range of 400 to 600 nm. When the light is reflected by the Dichroic mirror 35, the transmittance is 1×10⁻⁸ or less, which hardly affects the detection unit. The Dichroic mirror 35 has a transmittance of 95% or more in a range of 760 to 1200 nm, and has a reflection rate of 98% or more in a range of 420 to 660 nm. The excitation light having a wavelength of 405 nm is used in this design. Alternatively, a light source of 680 nm may be used when the filter configuration is changed. The purpose of the band-pass filter 14 is to passes the SHG light of 420 to 600 nm and blocks the fundamental light of 800 to 1200 nm. When the laser power is assumed to be 500 mW, the band-pass filter 14 has a performance of blocking the fundamental light in a level of 0.3 nW. The excitation light uses laser light of 405 nm, and the output thereof is set at about 3 mW. In this case, the output of the photomultiplier tube is 0.5 nW or less. In this configuration, the transmittance of the SHG light is 80% or more in a range of 420 nm to 600 nm except for 75% in a range of 420 nm to 425 nm.

The accurate position control of the objective lens OL is achieved with a combination of a Z-stage 39 and a piezo-stage (an embodiment of piezo-actuator) 29. Automatic Z-stage ZA07A-X1-R made by Kohzu Precision Co., Ltd. is used as the Z-stage. Regarding the accuracy, the automatic Z-stage ZA07A-X1-R has a minimum resolution of 0.25 μm and a movable range of ±10 mm. The piezo-stage is dedicated for the objective lens. The piezo-stage has a movable range of about 20 μm and a resolution of ±5 nm. With this combination, the required resolution is ensured.

The waveform is modified with the configuration as shown in FIG. 10. The light output from the wavelength conversion unit 2 enters into the iris diaphragm 25. The dimension of the iris diaphragm 25 can be changed from 1 to 10 mm. It is manually set at 5 mm. Thereafter, the output is attenuated by the attenuation filter 3. The attenuation filter 3 attached to the rotation control plate 26 is rotated, and the output emitted from the objective lens OL is uniformized. With the combination of the convex lens 37 and the concave lens 38, the controlled beam is made into a beam suitable for the aperture diameter 3.0 mm of the objective lens OL.

When the wavelength of the incident light changes in a range of 800 to 1200 nm, the focal points of the convex lens 37 and the concave lens 38 change, which no longer outputs collimated light. In order to correct this, the concave lens 38 is mounted on the X-stage 31. According to the above method, a corrected position is detected. The focal lengths are corrected by synchronizing the corrected position and the actuator 23 attached to the wavelength converter 2.

The focal point of the objective lens OL is corrected as follows. The waveform modifying unit corrects the focal point, and the correction is executed. Thereafter, collimated light is emitted into the objective lens OL. A detector (not shown) having a small light-receiving diameter (28 μmφ) is placed under the objective lens OL. First, a maximum output is detected when the wavelength is 800 nm. The objective lens OL is a 100× lens, which has a vision range of 0.22 mm. Accordingly, the position of the focal point of the objective lens OL can be sufficiently detected. Thereafter, the piezo-stage 29 is driven. Every time the wavelength is changed, a changed peak position is detected. Relationship between the values and the wavelengths is made into a table, so as to allow correction of the position.

A material used for an organic device generates SHG light intrinsic to the material. Therefore, when the fundamental wave is incident according to the wavelength of the intrinsic SHG light generated, the SHG light can be generated with an accuracy of 1 nm, i.e., the resolution of the laser oscillator 1. When the laser oscillator 1 has this resolution, the material can be sufficiently distinguished from another material. Therefore, this apparatus is arranged with a function for identifying the intrinsic SHG light.

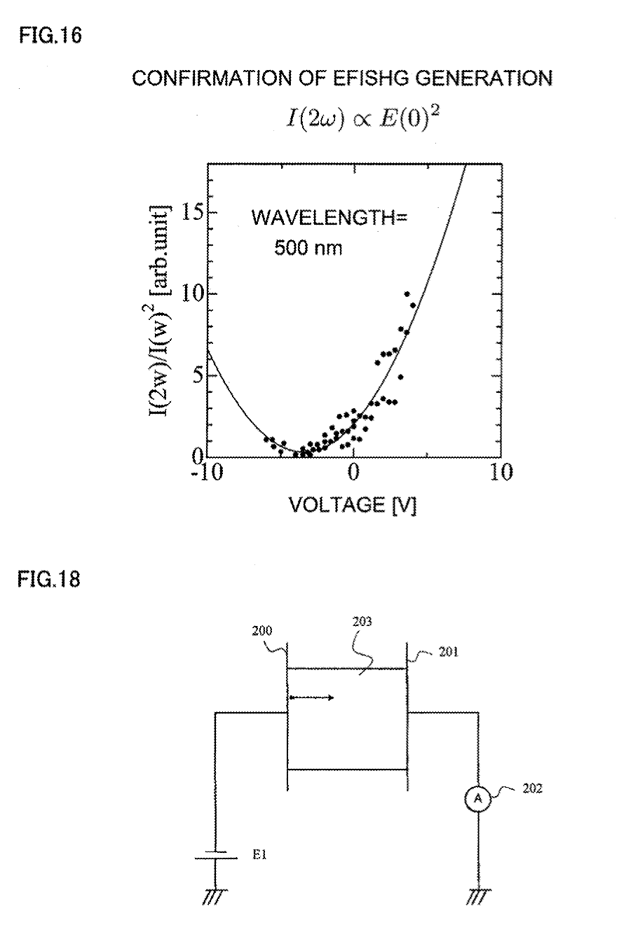

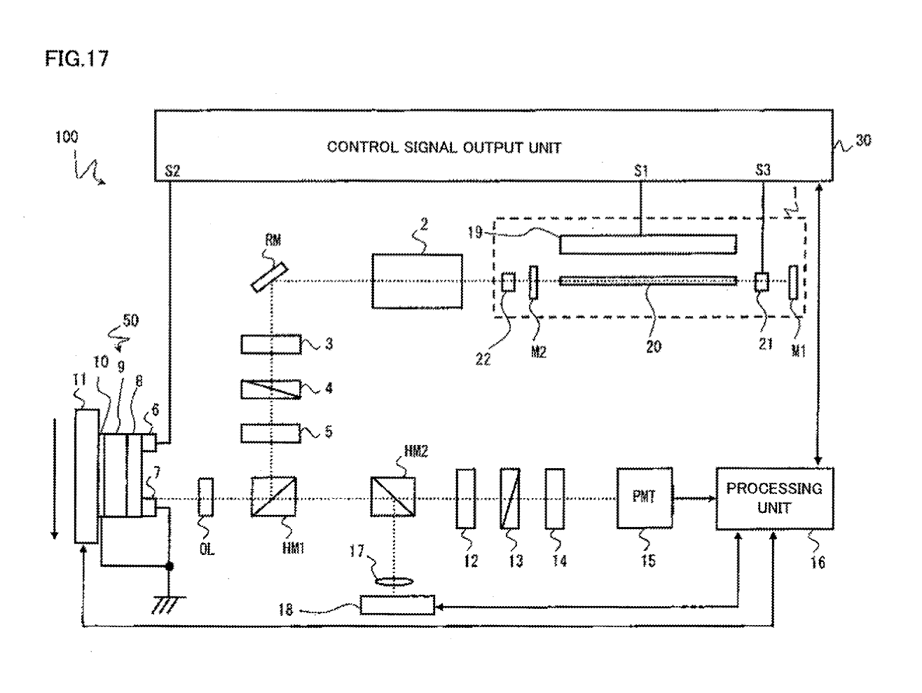

The measurement result at C60 is shown in FIG. 16. The fundamental wave is swept between 800 and 1200 nm to measure the SHG light. The intrinsic wavelength can be determined from the wavelength dependency. Whether the obtained intrinsic wavelength is of SHG light or not can be verified as follows. The rotation control plate 26 is driven, and the output of the fundamental wave is changed for the intrinsic wavelength. Then, since the SHG light has characteristics of the above expression (2), it is proportional to a square of the output. The obtained intrinsic wavelength can be determined to be of SHG light by checking this.

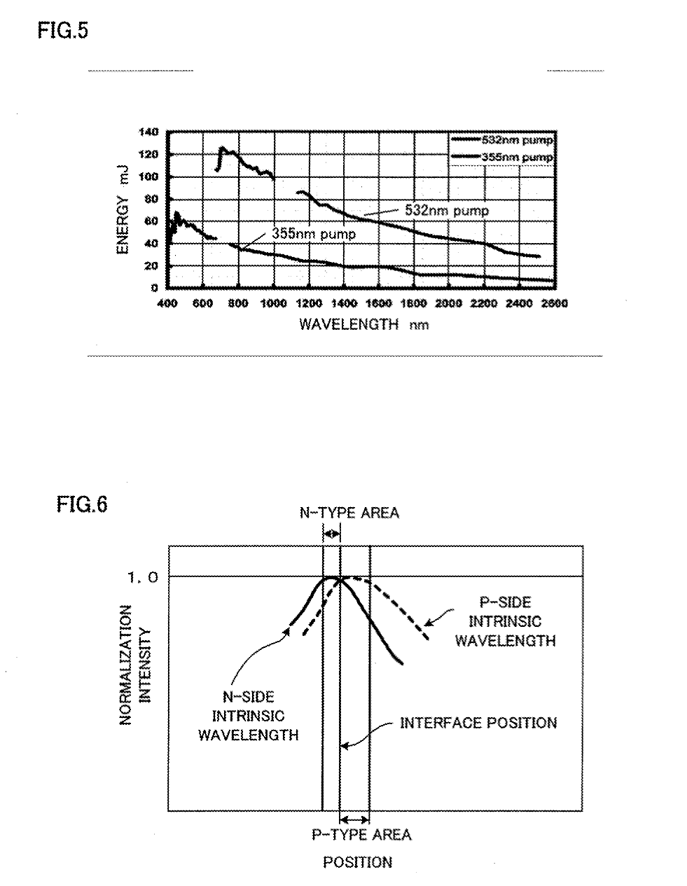

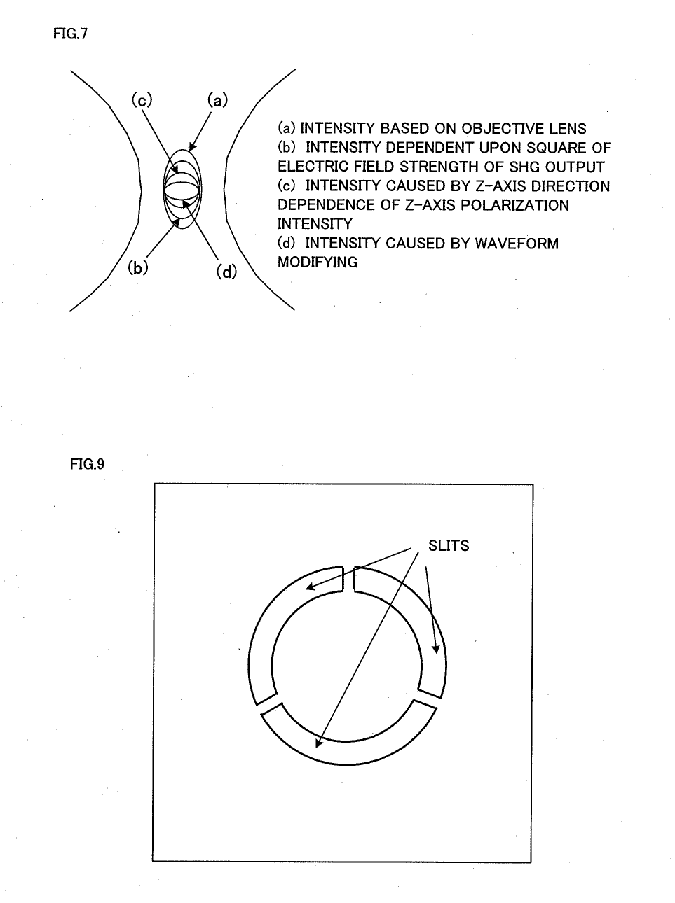

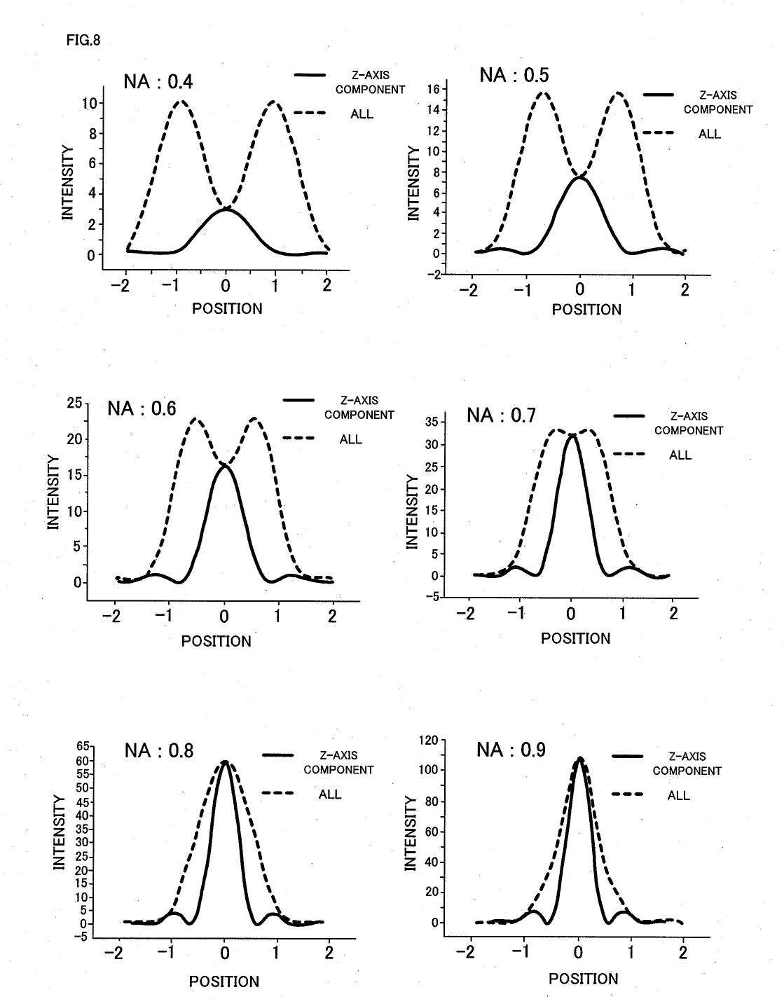

When the intrinsic wavelength of each material can be identified as described above, the position of the interface of the organic device can be identified using the wavelength. First, the focus is positioned onto the surface of the sample of the image capturing device 18 and the objective lens OL. Since design values of the organic device are already known, the SHG light having the intrinsic wavelength can be detected in this configuration as follows. The system is switched to a detection system, and thereafter, the position of the objective lens OL is set at a lower surface using the piezo-stage 29, and is gradually moved to an upper surface. Thus, the SHG light having the intrinsic wavelength can be detected. In a case of PN junction, this operation is repeated twice, and outputs of an N-side intrinsic wavelength and a P-side intrinsic wavelength are detected. Thereafter, normalization is performed with peak outputs thereof being 1. A point where the output results (curves) intersect with each other is a position of the interface (see FIG. 6).

According to the above method, information including many interfaces can be obtained using the intrinsic wavelength and the piezo-stage 29.

In order to improve the resolution of this apparatus in the optical axis direction, the focal depth is reduced. In other words, the focal distance is reduced, and the NA is increased. However, due to the limitation of the dimension of the sample, the NA cannot be increased blindly. Where a cover glass for the sample has a thickness of 0.5 mm, and the device has a thickness of 0.2 to 0.3 mm, a space of at least 0.2 mm is needed. Therefore, about 1.0 mm is needed as the focal depth. In this focal depth, the NA is limited to 0.9 or less.

There are three factors for determining the resolution of this apparatus in the optical axis direction. The first factor is detection of the SHG light. As can be seen from the expression (2), the output is proportional to a square of the intensity of the light. Therefore, when the intensity of the light attenuates 0.7, the output of the SHG light becomes 0.5, which improves the resolution.

Another factor is the intensity of the electric field applied to the sample as can be seen from the expression (1). In other words, it is dependent upon the intensity of the electric field generated by the Z-axis polarizer. This intensity is dependent upon the NA as shown in FIG. 8. This calculated value represents the intensity of the light at the focusing position. Therefore, even with the same NA, displacement from the focal point results in the same effect as that caused by decrease of the NA. This means that, at a position displaced from the focal point, the electric field is weaker in the optical axis direction, which reduces the intensity of the SHG light. As a result of this effect, the resolution is improved.

The third factor is a method for reducing an apparent focal depth. More specifically, in this method, a central portion of the laser light output from the wavelength converter 2 is covered with slits, and the donut-shaped light having passed through the slits is condensed, so that the focal depth is reduced. This method also improves the resolution. The three methods as described above are used to improve the resolution.

In order to improve the resolution in this method, it is understood that the condensing characteristics of the fundamental light is important. The condensing characteristics of the lens are determined by aberration, but the aberration has a wavelength dependency. Therefore, it is important to choose in which wavelength range the aberration of the lens is designed. Currently-available microscopes include a microscope for a visible light range and a microscope suitable for infrared light. In this apparatus, it is necessary to decrease the aberration of the fundamental wave, but it is necessary to increase the transmittance of the visible light as much as possible. This is to improve the sensitivity of the SHG light.

In an ideal case, the AR coat is required to have a high transparency in the entire area from 400 to 1200 nm. However, in terms of optics, such high performance is impossible. Therefore, it is required to design the lens in which the AR coat is adjusted for 400 to 600 nm and the aberration is adjusted for 800 to 1200 nm.

The following procedure is needed to measure a lifetime. First, the surface of the object to be observed is observed with the image capturing device 18, and the focal point of the objective lens OL is set at the surface of the object to be observed. Subsequently, the focal point of objective lens OL is lowered to the position where the organic material is present, and the fundamental wave is swept to respectively identify the intrinsic wavelengths. After the intrinsic wavelengths are identified, the intrinsic wavelengths are used to sweep the position of the piezo-stage 29, thereby identifying the position of the interface. After the position of the interface is identified, the objective lens OL is moved to the position calculated from the design value. Then, using the intrinsic wavelengths, a time of the SHG light is measured. Control signals are classified into two groups. They are a signal S1 for controlling the excitation light, signals S2, S3 for controlling laser lights, and signals S4, S5 for respectively controlling the photomultiplier tube and the integrator. The signals S2, S3, S4, S5 are controlled together.

After the Q switch is driven, a trigger signal is input to the laser oscillator 1. Then, after a certain period of time passes since the trigger signal, the laser oscillator 1 starts laser oscillation. This period of time is intrinsic to the apparatus. When 245 μs passes since the signal S2 is turned on, accumulation occurs. When 4.38 μs passes since then, a trigger signal is transmitted. When 100 ns passes since the trigger signal, laser oscillation starts. When 215 ns passes since a gate trigger of the gate-attached photomultiplier tube 15 is turned ON, the photomultiplier tube 15 attains the maximum detection sensitivity. Since, the pulse width of the laser light is several nanoseconds, it is impossible to obtain data unless the detection is made according to this timing. On the other hand, it takes 5 ns to drive the integrator 34. Therefore, times from when the laser is driven to when integration starts is as follows. As shown in FIG. 14, while the signals S2, S3, S4, S5 are synchronized, the above relationship is maintained, and the measurement is performed with the excitation light n times with an interval of m [ns]. Based on the result thereof, a decay time constant is measured, whereby the lifetime can be measured.

The lifetimes of electrons and holes can be measured by measuring the SHG lights intrinsic to different materials. Since hetero junction is formed, and materials are different, it is considered that the interface densities are different. Therefore, carrier disappearance is considered to be different between the electrons and holes, and the data thereof are considered to provide important information when the band states of organic devices are studied.

### Embodiment

A detection apparatus 100 as shown in FIG. 1 is structured. OPO excitation pulse YAG laser made by Continuum, Inc. and an optical parametric oscillator are employed as the laser oscillator 1 and the wavelength converter 2. A manual actuator is detached so as to automatically change the wavelength, and an automatic actuator 23 and a control unit 24 are attached. In this configuration, the wavelength of the fundamental wave can be automatically changed.

An iris diaphragm 25 is attached to a waveform modifying unit 52. Seven types of attenuation filters 3 are attached to a rotation control plate 26, so that the attenuation can be controlled in eight levels. Using the above attenuation filters 3 and the fixed attenuation filter 3, the attenuation can be controlled automatically. The output thereof passes through a convex lens 37 and a concave lens 38, so that the beam diameter is adjusted for an aperture diameter of an objective lens OL, i.e., 3 mm. The concave lens 38 is mounted on the X-stage 31, and the position of the concave lens 38 is automatically moved, so that the position of the focal point can be corrected.

The light having passed through the waveform modifying unit 52 enters into a Z-axis polarizer 27 via a reflection mirror RM. The position of the Z-axis polarizer 27 is determined as follows. An XY stage 28 is driven, and the light is reflected by a slide-type reflection mirror RM′, and is guided to an image capturing device 18 via an attenuation filter 3 and a polarizer 4. The position of the Z-axis polarizer 27 is adjusted so that a butterfly shape becomes symmetrical as shown in FIG. 11C. Thereafter, the slide-type reflection mirror RM′ is driven, so that the light enters into the objective lens OL via a Dichroic mirror 35. As a result, the fundamental wave is emitted onto the object to be observed.

The NA of the objective lens OL is 0.9, and the working distance is 1.0 mm. A correction tube is attached to the lens, so as to correct the refractive index of the cover glass.

The objective lens OL is mounted on a piezo-stage 29, and the piezo-stage 29 has a movable range of 20 μm and a resolution of 5 nm. The piezo-stage 29 is mounted on a Z-stage 39, and the Z-stage 39 has a movable range of 20 mm and a resolution of 0.5 μm. This movable portion and the detection unit are coupled via a bellows (not shown), and are shielded from any external light.

The SHG light generated by the fundamental wave is condensed by the objective lens OL, and is reflected by the Dichroic mirror 35. Then, the SHG light is guided to the detection unit. In the detection unit, the SHG light passes through a band-pass filter 14 and a band-pass filter 14′ inclined 45 degrees, and passes through the slide-type reflection mirror RM′. Then, the SHG light is guided to a photomultiplier tube 15, and is transmitted to an integrator 34 via an amplifier (not shown). The integrator 34 outputs it as data.

The intrinsic wavelength is identified as follows. First, the wavelength is swept to obtain SHG light. Subsequently, the rotation control plate 26 is driven at the wavelength, and a determination is made as to whether the SHG light has square-law characteristic or not by changing the output of the fundamental wave. When the SHG light is determined to have the square-law characteristic, it is adopted as the intrinsic wavelength. FIG. 15 illustrates an example of the intrinsic wavelength. The data are of C60, and are at 500 nm. In a case of pentacene, data are present at a position of 430 nm. Dynamic characteristics of the organic device in a particular area can be obtained by using the intrinsic wavelength.

Subsequently, a method for identifying an interface will be explained using an example of an organic solar cell. In the measurement example, C60 of 100 nm, pentacene of 100 nm, and ITO attached cover glass of 500 μm are provided on an electrode substrate. First, the sample is set on the apparatus, and while light source 32 is emitted, the Z-stage 39 is driven. The surface of the solar cell is observed with the image capturing device 18. The Z-stage 39 is stopped when the focus is obtained. Subsequently, since the thickness of the cover glass is 500 μm, the Z-stage 39 is lowered, and the correction tube is moved, so that the focus is obtained there.

Subsequently, the objective lens OL is lowered 2 μm with the piezo-stage. A fundamental wave of 1000 nm is output from there, and while the output of C60 is measured, the objective lens OL is moved upward 3 μm. Subsequently, it is lowered 3 μm again. This time, a fundamental wave of 860 nm is output, and the objective lens OL is moved upward 3 μm. Then, the same measurement is performed. Subsequently, each piece of data is normalized, and the position of the interface is identified based on the intersecting point. The thickness of C60 identified with the above operation was 110 nm.

The measurement procedure of the lifetime is performed as follows.

The control signal output unit 30 outputs the following signal. A start signal is output from a signal S1 to turn ON excitation light. The signal is cut off in 249.47 μs. A signal S2 is triggered at the rise of S1 signal. 245 μs later, it is ready to receive a gate signal. A signal S3 is triggered 249.38 μs later. Accordingly, 100 ns later, a fundamental wave is output. This means that the fundamental wave is output after 10 ns since the excitation light is cut off. Regarding the gate signal of the photomultiplier tube 15, S4 is output at a position of 215 ns before output of the fundamental wave. Before the above, at 10 ns, a signal S5 for driving an integrator is output, so that SHG light is retrieved. In a subsequent step, the steps S2, S3, S4, S5 are delayed 10 ns with respect to the signal S1. This is performed successively until a time when the output becomes the same as the non-excited state. It is to be understood that the configured time, 10 ns, can be changed and set in a range from about 10 ns to about 10 ms.

In the above configuration, the apparatus was driven, and the solar cell including pentacene and C60 was measured. 4×10⁻⁴ sec was obtained as the lifetime of the pentacene. 1.0×10⁻³ sec was obtained as the lifetime of the C60. These values have not hitherto been measured, and we have to further study the reliability of these values. In any case, we have found that this apparatus can measure these parameters.

The present invention relates to an apparatus capable of detecting injection, accumulation, transport, generation, and disappearance processes of carrier, i.e., dynamic characteristics of organic semiconductors. Accordingly, the present invention can be applied to electroluminescence, photoelectromotive force, carrier transport devices, and in particular, to analysis of generation and disappearance processes. Therefore, the present invention can be applied to a wide range of subjects such as analysis of lifetime of electroluminescence, analysis of photoelectric conversion efficiency of photoelectromotive force, findings about interface mobility of an organic semiconductor, and the like.

In particular, in order to improve the photoelectric conversion efficiency of a solar cell, it is necessary to start consideration from structures, materials, and processes. Although cut-and-try researches have hitherto been made, information obtained with this detection apparatus is expected to greatly contribute to the improvement.

1. A detection apparatus for detecting, on the basis of high-order harmonics, an electric field distribution or a carrier distribution between electrodes arranged on an object to be observed, the detection apparatus comprising:
an emission unit for emitting a fundamental wave to the object;
a detection unit for detecting the high-order harmonics generated according to the electric field distribution or the carrier distribution in the object when an external stimulus is applied to the object;
an excitation emission unit for emitting an excitation light for generating a carrier in the object; and
a control signal output unit for outputting a second signal to cause the excitation emission unit to emit the fundamental wave to the object on the basis of a first signal of the excitation emission unit, and outputting a third signal to cause the detection unit to detect the high-order harmonics,
wherein the control signal output unit is configured to change a time interval from when the first signal is output to when the second and third signals are output.

2. A detection apparatus for detecting, on the basis of high-order harmonics, an electric field distribution or a carrier distribution between electrodes arranged on an object to be observed, the detection apparatus comprising:
an emission unit for emitting a fundamental wave to the object;
a detection unit for detecting the high-order harmonics generated according to the electric field distribution or the carrier distribution in the object when a voltage is applied to the object;
an excitation emission unit for emitting an excitation light for generating a carrier in the object; and
a control signal output unit for outputting a second signal to cause the excitation emission unit to emit the fundamental wave to the object on the basis of a first signal of the excitation emission unit, and outputting a third signal to cause the detection unit to detect the high-order harmonics,
wherein the control signal output unit is configured to change a time interval from when the first signal is output to when the second and third signals are output.

3. The detection apparatus according to claim 2, wherein the emission unit includes a polarizer (Z-axis polarizer) for arranging polarization in an optical axis (Z axis) direction, whereby the high-order harmonics generated according to the electric field distribution or the carrier distribution in the optical axis direction of the object are detected.

4. The detection apparatus according to claim 3, wherein the Z-axis polarizer is any one of:
one or a plurality of liquid crystals;
a polarizer including one or a plurality of photonic crystals;
a polarizer structured using one or a plurality of conical Brewster prism structures; and
a Z-axis polarizer having a structure made by attaching Polarcors to a polygon for setting off X-Y components.

5. The detection apparatus according to claim 2, wherein the excitation light is introduced from a side of the detection unit, and one or a plurality of filters for passing the high-order harmonics but blocking the fundamental wave and the excitation light are provided between the object and the detection unit, so that the detection unit measures disappearance of the carrier after the carrier excitation.

6. The detection apparatus according to claim 2, wherein a waveform modifying unit and the objective lens are provided between the emission unit and the object, and the waveform modifying unit modifies the light into a beam diameter appropriate for an aperture of the objective lens, and wherein the objective lens is mounted on a complex-stage constituted by a Z-stage and a piezo-actuator, and is accurately controlled in the Z axis direction, so that a SHG light output dependent upon an identified position is detected.

7. The detection apparatus according to claim 6, wherein the waveform modifying unit includes a diaphragm or a slit, an attenuation filter, a convex lens, and a concave lens, and wherein the concave lens is mounted on an X-stage, so that a change of a focal length based on a wavelength occurring in a lens system due to a change of wavelength of the emission unit is corrected by moving the X-stage in an synchronized manner.

8. The detection apparatus according to claim 6, wherein the change of the focal length caused by a change of a wavelength occurring in the objective lens is corrected by changing the wavelength and the piezo-actuator in an synchronized manner.

9. The detection apparatus according to claim 6, wherein the waveform modifying unit is provided with means having variable attenuation function for correcting an intensity of output of the fundamental wave, thereby uniformizing the intensity of output of the fundamental wave within a setting range including an output change of the fundamental wave emitted by the emission unit, a transmittance characteristic of the objective lens, and various filters provided between the emission unit and the objective lens.

10. The detection apparatus according to claim 6, wherein when the output of the high-order harmonics is detected, sensitivity uniformizing correction is performed with respect to wavelength characteristics of various filters provided between the objective lens and a photomultiplier tube and an AR coat of the objective lens.

11. The detection apparatus according to claim 2, wherein the emission unit is constituted by a variable wavelength laser, and manually or automatically drives a crystal resonator, and wherein the emission unit has a function of emitting the generated fundamental wave to the object, sweeping a wavelength spectrum, and identifying a high-order harmonic intrinsic to a material constituting the object.

12. The detection apparatus according to claim 9, wherein after the high-order harmonic intrinsic to the material is identified, a fundamental wave corresponding to each material is set, and while this fundamental wave is emitted, it is accurately moved to a position in the optical axis direction, and wherein a positional dependency of the high-order harmonics generated by the object is measured, and the measurement is applied to different materials, and the characteristics thereof are normalized, whereby a position of an interface between materials of the object is identified based on an intersecting position of the characteristics.

13. The detection apparatus according to claim 6, wherein in order to reduce a generation depth of the high-order harmonics generated by the object, a numerical aperture of the objective lens is increased from an original value, and X, Y axes components in the polarization plane are reduced.

14. The detection apparatus according to claim 6, wherein in order to reduce a generation area of the high-order harmonics generated by the object, a donut-shaped slits is attached to a diaphragm portion of the waveform modifying unit, whereby a depth of focus of the beam of the objective lens is reduced.

15. The detection apparatus according to claim 10, wherein the objective lens used for emitting the light to the object is designed such that a target range of aberration correction is 800 to 1200 nm, and the AR coat is designed for 400 to 600 nm, whereby blur of the fundamental wave is prevented, and the sensitivity of detection of the high-order harmonics is improved.

16. The detection apparatus according to claim 2, wherein after the excitation emission unit emits the excitation light to generate the carrier in the object and stops the emission, observation is successively performed while controlling a time with the control signal output unit, and a decay time constant is calculated from data thereof, so that a lifetime of a carrier of a material is measured.

17. The detection apparatus according to claim 2, wherein a fundamental wave intrinsic to a material of the object is selected, and the selected fundamental wave is used, so that a lifetime of each carrier in an area intrinsic to a material of the object is measured.

18. The detection apparatus according to claim 3, wherein the excitation light is introduced from a side of the detection unit, and one or a plurality of filters for passing the high-order harmonics but blocking the fundamental wave and the excitation light are provided between the object and the detection unit, so that the detection unit measures disappearance of the carrier after the carrier excitation.

19. The detection apparatus according to claim 4, wherein the excitation light is introduced from a side of the detection unit, and one or a plurality of filters for passing the high-order harmonics but blocking the fundamental wave and the excitation light are provided between the object and the detection unit, so that the detection unit measures disappearance of the carrier after the carrier excitation.

20. The detection apparatus according to claim 3, wherein a waveform modifying unit and the objective lens are provided between the emission unit and the object, and the waveform modifying unit modifies the light into a beam diameter appropriate for an aperture of the objective lens, and wherein the objective lens is mounted on a complex-stage constituted by a Z-stage and a piezo-actuator, and is accurately controlled in the Z axis direction, so that a SHG light output dependent upon an identified position is detected.
